(19) United States
(12) Patent Application Publication
(10) Pub. No.: US 2014/0322646 A1
(43) Pub. Date: Oct. 30, 2014

(54) ABLATION IMAGEABLE LITHOGRAPHIC PRINTING PLATE

(71) Applicants: Moshe Nakash, Ramat Hasharon (IL); Daniel Weizman, Ramat Gan (IL)

(72) Inventors: Moshe Nakash, Ramat Hasharon (IL); Daniel Weizman, Ramat Gan (IL)

(21) Appl. No.: 13/870,056

(22) Filed: Apr. 25, 2013

(51) Int. Cl. G03F 7/038

(52) U.S. Cl. CPC G03F 7/0387
USPC 430/270.1; 430/302

(57) ABSTRACT

A positive-working, ablation-imagable lithographic printing plate precursor can be imaged and used for lithographic printing without wet processing. This precursor has a sulfuric acid or phosphoric acid anodized aluminum-containing substrate, a crosslinked hydrophilic inner layer comprising a crosslinked polymer derived by using a crosslinking agent that comprises at least two aldehyde groups, and an acidic compound. Over the crosslinked hydrophilic inner layer is an oleophilic outer layer comprising an infrared radiation absorber and an oleophilic polymer. The precursor also has a copolymer comprising randomly recurring units derived from each of a (meth)acrylamide and vinyl phosphonic acid. This copolymer is present either within the crosslinked hydrophilic inner layer, as part of a different copolymer layer between the crosslinked hydrophilic inner layer and the substrate, or in both places.

### FIELD OF THE INVENTION

This invention relates to positive-working ablation imagable lithographic printing plate precursors having at least two adhered layers on an anodized aluminum substrate. Such lithographic printing plate precursors can be used for lithographic printing after imaging without further treatment such as wet processing.

### BACKGROUND OF THE INVENTION

Offset lithographic printing has remained important in many areas of printing for several reasons. For continual printing methods, offset lithography has provided simplicity, cost-effectiveness, and high print quality.

Modern technology permits the generation of all kinds of digital data including images, text, and collections and arrangements of data in personal computers or other storage devices in a way that is useful in the generation of printed copy. The data are then directed to a CTP (Computer-to-Plate) device where it is used to modulate a laser (or array of lasers) that “writes” the digital data onto lithographic printing plate precursors. The resulting latent images in the precursors generally require wet processing in a developer to differentiate the regions that will accept ink from the background regions that reject ink during the printing process.

The concept of using laser energy to digitally image printing plates has closely followed the development of lasers. Early lasers were powerful but slow and expensive compared to chemical etching techniques. The laser power required at a given spot and power generated heat were both quite high. The material had to be completely vaporized for an interval sufficient to ensure its removal. Consequently, there was a great quantity of thermal energy transferred to the surrounding area that had to be removed before another spot could be etched. Clearly, the art had not progressed to the level where the thermal energy could be removed quickly enough to enable laser etching to compete in speed with chemical etching. In addition to slow production, the printing plates produced images that were unacceptably irregular and lacking in definition. A suitable exposure system would use argon ion, helium-cadmium, and other lasers of like nature to image commercially available diazo-sensitized layers on aluminum supports. The imaged printing plates were then processed using a developer.

U.S. Pat. No. 4,054,094 (Caddell et al.) describes the imaging of a lithographic printing plate precursor that has an aluminum base coated with a hydrophilic coating using a laser to burn away the coating and causing the aluminum surface to become oleophilic in the imaged areas leaving hydrophilic areas of the substrate. Such laser “burning” has become known as laser ablation.

An additional approach to simplification of the offset lithographic printing process is described in U.S. Pat. No. 3,511,178 (Curtin) in which the concept of waterless printing was introduced by using printing plate precursors coated with polydimethyl siloxane (silicone) that preferentially rejected ink during printing and formed the areas corresponding to the background. GB Patent Publication 1,489,308 (Eames) describes a combination of waterless printing and laser ablation.

The concepts described in this art are expensive, slow, and require high power. A significant advantage of using laser ablation for imaging is that as the ablated material is destroyed, minimal wet solution development is needed after imaging. Ideally, imaging by ablation should require no such processing solutions but in practice this is not the case. If the ablated printing plate could be used without the need for a cleaning process, the making of printing plates would be significantly simplified because even the simplest water washing step and processor unit could be eliminated. Even a drying step could be avoided.

Other researchers in recent years sought to produce conventional wet offset lithographic printing plate precursors that are imaged by laser ablation but the imaged precursors still require treatment to remove debris. Lithographic printing plate formulations have been specifically designed to allow for cleaning with the simplest of solutions, such as water.

U.S. Pat. Nos. 6,182,569, 6,182,570, and 6,192,798 (all Rorke et al.) describe the problems of formulations designed to accommodate post-imaging development. In these patents, it was attempted to formulate protective layers that would not be harmed by processing solutions.

U.S. Patent Application Publication 2012/0189770 (Nakash et al.) describes lithographic printing plate precursors having low sensitivities so that high imaging energy can be used. The internal portion of the oleophilic surface layer in these precursors is generally non-crosslinked. The interface of the oleophilic surface layer can be crosslinked as it is chemically bound to the underlying layer. The ablatable oleophilic surface layer desirably has high solvent resistance but is generally non-crosslinked.

In addition, copending and commonly assigned U.S. Ser. No. 13/597,395 (filed Aug. 29, 2012 by Nakash and Weitzman) describes improved method for using laser ablation. The lithographic printing plates prepared using this method exhibit improved printing press durability because of the use of specific anodic oxide surface pore size in the aluminum substrate obtained using phosphoric acid anodization and a crosslinked hydrophilic inner layer and oleophilic surface layer.

While the noted method provides a significant advance in the art for laser ablation imaging, there is a desired to provide lithographic printing plates that exhibit improved durability (longer print runs) on the printing press. Moreover, there is a need to obtain these results using aluminum substrates that are anodized with either phosphoric acid or sulfuric acid. While it is more common and more economical to use aluminum substrates that are anodized with sulfuric acid, it has been particularly difficult to achieve good run length when such substrates are used as part of lithographic printing plates having a crosslinked hydrophilic inner layer and an oleophilic surface layer.

### SUMMARY OF THE INVENTION

To address the noted problem, the present invention provides a positive-working, ablation-imagable lithographic printing plate precursor comprising, in order:

a sulfuric acid or phosphoric acid anodized aluminum-containing substrate,

a crosslinked hydrophilic inner layer comprising; (1) a crosslinked polymer derived by crosslinking a hydrophilic polymer comprising randomly recurring units represented by —CH₂—CH(OH)— in an amount of at least 70 mol % of the total recurring units, using a crosslinking agent for the —CH₂—CH(OH)— recurring units that comprises at least two aldehyde groups, and (2) an acidic compound,

over the crosslinked hydrophilic inner layer, an oleophilic outer layer comprising: (a) an infrared radiation absorber, and (b) at least one oleophilic polymer that comprises at least 10 mol % randomly recurring units represented by —CH₂—CH(OH)—, based on the total recurring units, and

the crosslinked hydrophilic inner layer and the oleophilic outer layer forming a composite structure of the two layers,

the positive-working, ablation-imagable lithographic printing plate precursor further comprising a copolymer comprising randomly recurring units derived from each of a (meth)acrylamide and vinyl phosphonic acid,

wherein the copolymer is present either:

(a) within the crosslinked hydrophilic inner layer,

(b) within a different copolymer layer between the crosslinked hydrophilic inner layer and the sulfuric acid or phosphoric acid anodized aluminum-containing substrate, or

(c) both (a) and (b).

The present invention also provides a method for providing a lithographic printing plate, comprising:

imagewise exposing any embodiment of the positive-working ablation-imagable lithographic printing plate precursor of the present invention to remove the oleophilic outer layer in exposed regions by ablation to prepare a lithographic printing plate ready for printing without further treatment or processing.

Such a lithographic printing plate can be used for lithographic printing without intermediate contact with a solution after the imagewise exposing.

Further, the present invention provides a method for preparing any embodiment of the positive-working, ablation-imagable lithographic printing plate precursor of this invention, this method comprising:

providing a sulfuric acid or phosphoric acid anodized aluminum-containing substrate,

over the sulfuric acid or phosphoric acid anodized aluminum-containing substrate, providing a crosslinked hydrophilic inner layer by applying an inner layer formulation comprising: (1) a hydrophilic polymer that comprises randomly recurring units represented by —CH₂—CH(OH)— in an amount of at least 70 mol % of the total recurring units, (2) a crosslinking agent for the —CH₂—CH(OH)— recurring units that comprises at least two aldehyde groups, and (3) an acidic compound,

over the crosslinked hydrophilic inner layer, providing an oleophilic outer layer by applying an outer layer formulation comprising: (a) an infrared radiation absorber, and (b) at least one oleophilic polymer that comprises at least 10 mol % randomly recurring units represented by —CH₂—CH(OH)—, based on the total recurring units, dissolved or dispersed within an organic solvent solution, and drying to form a composite structure consisting of the crosslinked hydrophilic inner layer and the oleophilic outer layer, and

the method further comprising:

providing a copolymer comprising randomly recurring units derived from both a (meth)acrylamide and vinyl phosphonic acid,

wherein the copolymer is provided either:

(a) as part of the inner layer formulation,

(b) by applying a different layer of the copolymer directly to the sulfuric acid or phosphoric acid anodized aluminum-containing substrate before applying the inner layer formulation, or

(c) both (a) and (b).

The present invention provides a positive-working ablation-imagable lithographic printing plate precursor that can be used to provide lithographic printing plates with improved printing durability. These improved results can be achieved when the aluminum-containing substrate is anodized with either phosphoric acid or sulfuric acid.

These advantages are achieved in the precursors of the present invention with a specific incorporated copolymer in either or both of two places. In some embodiments, a copolymer derived from each of a (meth)acrylamide and vinyl phosphonic acid is incorporated into the crosslinked hydrophilic inner layer of the precursor. In other embodiments, this copolymer is incorporated as a separate layer between the crosslinked hydrophilic inner layer and the acid anodized aluminum substrate.

### DETAILED DESCRIPTION OF THE INVENTION

### Definitions

Unless otherwise indicated herein, the terms “precursor,” “positive-working ablation-imagable lithographic printing plate precursor,” “lithographic printing plate precursor,” and “printing plate precursor” are all intended to refer to embodiments of the present invention.

As used herein to define various components of the various layers, formulations, and solutions, unless otherwise indicated, the singular forms “a,” “an,” and “the” are intended to include one or more of the components (that is, including plurality referents).

Each term that is not explicitly defined in the present application is to be understood to have a meaning that is commonly accepted by those skilled in the art. If the construction of a term would render it meaningless or essentially meaningless in its context, the term definition should be taken from a standard dictionary.

The use of numerical values in the various ranges specified herein, unless otherwise expressly indicated otherwise, are considered to be approximations as though the minimum and maximum values within the stated ranges were both preceded by the word “about”. In this manner, slight variations above and below the stated ranges can be used to achieve substantially the same results as the values within the ranges. In addition, the disclosure of these ranges is intended as a continuous range including every value between the minimum and maximum values.

Unless the context indicates otherwise, when used herein, the terms “lithographic printing plate” and “printing plate” are considered to refer to the same element that is derived from a lithographic printing plate precursor.

Unless otherwise indicated, percentages refer to percents by weight. Percent by weight can be based on the total solids in a formulation or composition, or on the total dry weight of a layer.

As used herein, the term “infrared radiation absorbing compound” refers to a material that is sensitive to at least one peak wavelength of near infrared and infrared radiation and can convert photons into heat within the layer in which they are disposed. These compounds can also be known in the art as “photothermal conversion materials”, “sensitizers”, or “light to heat converters”.

For clarification of definition of any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any different definitions set forth herein should be regarded as controlling.

Unless otherwise indicated, the term “polymer” refers to high and low molecular weight polymers including oligomers and can include both homopolymers and copolymers.

The term “copolymer” refers to polymers that are derived from two or more different ethylenically unsaturated polymerizable monomers, or have two or more different types of recurring units, even if derived from the same type of monomer. Unless otherwise noted, the different constitutional recurring units are present in random order along the copolymer backbone.

The term “backbone” refers to the chain of atoms in a polymer to which a plurality of pendant groups are attached. An example of such a backbone is an “all carbon” backbone obtained from the polymerization of one or more ethylenically unsaturated polymerizable monomers. However, other backbones can include heteroatoms wherein the polymer is formed by a condensation reaction of some other means.

### Lithographic Printing Plate Precursors

The lithographic printing plate precursors prepared according to the present invention are positive-working imagable elements so that imaged (exposed) regions in the oleophilic outer layer are substantially removed during imaging and the non-imaged (non-exposed) regions of the oleophilic outer layer remain in the imaging surface of the resulting lithographic printing plate. Any debris can be removed by dry cleaning or in the fountain solution during printing.

Copolymers:

The copolymers useful in the practice of the present invention comprise randomly recurring units derived from each of a (meth)acrylamides and vinyl phosphonic acid. The recurring units are arranged randomly along the polymer carbon backbone rather than in purposely designed blocks of the same type of recurring unit.

For example, the copolymer can comprises at least 70 mol % of randomly recurring units derived from a (meth)acrylamide and at least 5 mol % of recurring units derived from vinyl phosphonic acid, based on total recurring units in the copolymer. More likely, the copolymer comprises at least 80 mol % and up to and including 90 mol % of randomly recurring units derived from a (meth)acrylamide and at least 10 mol % and up to and including 20 mol % of recurring units derived from vinyl phosphonic acid, based on total recurring units in the copolymer.

The (meth)acrylamide ethylenically unsaturated polymerizable monomers include acrylamides, methacrylamide, as well as substituted methacrylamide, N-ethyl acrylamide, and N-isopropyl acrylamide. Methacrylamide and acrylamides are particularly useful. Mixtures of (meth)acrylamides can be used if desired.

In many embodiments, the copolymer consists only of randomly recurring units derived from each of a (meth)acrylamide and vinyl phosphonic acid. In such embodiments, there are no other recurring units in the copolymers.

However, in other embodiments, the copolymer further comprises up to and including 25 mol %, or typically at least 1 mol % and up to and including 15 mol %, randomly recurring units derived from one or more ethylenically unsaturated polymerizable monomers other than (meth)acrylamides and vinyl phosphoric acid. The amount of these recurring units is based on the total recurring units in the copolymer. Representative useful additional ethylenically unsaturated polymerizable monomers include but are not limited to, acrylic acid, methacrylic acid, acrylonitrile, methyl acrylate, and methyl methacrylate.

The copolymers used in the present invention are generally prepared using emulsion polymerization techniques that are well known to polymer chemists. Some useful copolymers are readily purchased from various commercial sources.

The copolymers described herein can be incorporated into the precursor of this invention in either of two places, or in both places (different copolymers can be used in the different places). In some embodiments, the one or more of these copolymers are incorporated within the crosslinked hydrophilic inner layer (described below) by including it into the hydrophilic inner layer formulation (also described below).

In other embodiments, one or more of the copolymers are incorporated as a separate copolymer layer directly disposed between the crosslinked hydrophilic inner layer and the sulfuric acid or phosphoric acid anodized aluminum substrate. Details of this separate copolymer layer are provided below.

Aluminum-Containing Substrates:

The method of the present invention requires the use of an anodized aluminum-containing substrate comprising an anodic oxide surface as described below. The resulting anodized aluminum-containing substrate generally has a hydrophilic surface that is more hydrophilic than the oleophilic outer layer on the imaging side. The anodized aluminum-containing substrate is usually in the form of a sheet, film, or foil, and is strong, stable, flexible, and resistant to dimensional change under conditions of use so that color records will register a full-color image.

To form the anodized aluminum-containing substrates, an aluminum support is generally physically, chemically, or electrochemically grained. Following graining, the grained aluminum support is anodized to provide the desired anodic oxide surface. Such anodization can be carried out using any suitable technique that provides these properties.

For example, an electrochemically grained aluminum support can be anodized in an alternating current passing through a sulfuric acid solution (5-30 weight %) at a temperature of at least 20° C. and up to and including 60° C. for at least 5 seconds and up to and including 250 seconds to form an oxide layer on the metal surface. Generally, sulfuric acid anodization is carried out to provide an aluminum oxide layer of at least 0.3 g/m² and typically at least 1 g/m² and up to and including 10 g/m², or up to and including 5 g/m². Sulfuric acid anodized aluminum-containing substrates are particularly useful as the advantages of the present invention are more evident with such substrates.

If desired, the electrochemically grained and sulfuric acid or phosphoric acid anodized aluminum-containing substrates can be additionally treated to widen the pores in the aluminum oxide layer (“pore-widening treatment”) so that the diameter of the columnar pores at their outermost surface (that is, nearest the outermost layer surface) is at least 90%, and more typically at least 92%, and even more than 100% of the average diameter of the columnar pores. The average diameter of the columnar pores can be measured using a field emission scanning electron microscope. Once this average diameter is determined, it is possible to determine whether the diameter at the outermost surface is at least 90% of that average diameter value using similar measuring techniques.

The columnar pores can be widened using an alkaline or acidic pore-widening solution to remove at least 10 weight % and up to and including 80 weight %, typically at least 10 weight % and up to and including 60 weight %, or more likely at least 20 weight % and up to and including 50 weight %, of the original aluminum oxide layer. Pore widening can thus be accomplished using an alkaline solution containing sodium hydroxide, potassium hydroxide, lithium hydroxide, or mixtures of hydroxides, having a pH of at least 11 and up to and including 13, or more likely having a pH of at least 11.5 and up to and including 12.5, and a hydroxide (such as a sodium hydroxide) concentration of at least 0.15 g/l and up to and including 1.5 g/l. The alkaline or acidic pore-widening solution generally has conductivity of at least 0.8 mS/cm and up to and including 8.2 mS/cm. Further details of these sulfuric acid anodizing and pore widening processes are provided in copending and commonly assigned U.S. patent application Ser. No. 13/221,936, (filed Aug. 31, 2011 by Hayashi), the disclosure of which is incorporated herein by reference.

Optionally, the anodized aluminum-containing substrate can be also post-treated with, for example, a silicate, dextrin, calcium zirconium fluoride, hexafluoro-silicic acid, phosphate/sodium fluoride, polyvinyl phosphonic acid) (PVPA), vinyl phosphonic acid copolymer, poly(acrylic acid), or acrylic acid copolymer solution, or an alkali salt of a condensed aryl sulfonic acid as described in GB 2,098,627 and Japanese Kokai 57-195697A (both Hefting et al.). For example, the grained and anodized aluminum-containing substrate can be treated with a polymer derived in whole or part from acrylic acid or methacrylic acid using known procedures to improve surface hydrophilicity. For example, the hydrophilic polymer can have at least 70 mol % of randomly recurring units derived from acrylic acid, methacrylic acid, or both, based on total recurring units in the hydrophilic polymer. The dry coverage of the layer that results from this post-treatment can be at least 30 mg/m² up to and including 300 mg/m². This layer thereby becomes a part of the anodized aluminum-containing substrate.

The thickness of the anodized aluminum-containing substrate can be varied but it should be sufficient to sustain the wear from printing and thin enough to wrap around a printing form. For example, it can have a thickness of at least 0.1 mm and to and including 0.5 mm.

The backside (non-imaging side) of the anodized aluminum-containing substrate can be coated with antistatic agents or slipping layer or matte layer to improve handling and “feel” of the positive-working lithographic printing plate precursors.

The anodized aluminum-containing substrate can also be in cylindrical form having the desired layers applied thereon, and can thus be an integral part of the printing press. The preparation and use of such imagable cylinders as precursors are described for example in U.S. Pat. No. 5,713,287 (Gelbart) the disclosure of which is incorporated herein by reference.

Separate Copolymer Layer:

As described above, in some embodiments, a separate copolymer layer comprising one or more copolymers as described above is disposed on the anodized aluminum-containing substrate. There are no additional layers between the separate copolymer layer and the overlying crosslinked hydrophilic inner layer and the underlying surface of the anodized aluminum-containing substrate. When dried, this separate copolymer layer has a typical dry coverage of at least 0.001 g/m² and up to and including 0.1 g/m², or more likely at least 0.005 g/m² and up to and including 0.01 g/m². The separate copolymer layer can be applied out of the solution or dispersion in which it is manufactured (or purchased), or the copolymer solution can be formulated with suitable coating solvents. The separate copolymer layer can be applied by dipping the anodized aluminum-containing substrate into a solution of the copolymer at a concentration of at least 0.1 g/l and up to and including 50 g/l for a period of at least 5 seconds and for up to and including 1 minute at a temperature of at least 30° C. and up to and including 80° C., and then removing the excess copolymer solution by rinsing the thus treated anodized substrate with water.

Crosslinked Hydrophilic Inner Layer:

A crosslinked hydrophilic inner layer is provided over the anodic oxide surface of the anodized aluminum-containing substrate (or over the separate copolymer layer if present) by suitably applying an inner layer formulation in a suitable manner, and suitably drying. This first essential layer in the lithographic printing plate precursor comprises one or more hydrophilic polymers, each of which comprises randomly recurring units represented by —CH₂—CH(OH)— in an amount of at least 70 mol % and up to and including 100 mol %, and typically at least 70 mol % and up to and including 99.5 mol %, of the total recurring units.

For example, such hydrophilic polymers can include but are not limited to, poly(vinyl alcohol) having a hydrolysis value greater than 99%, or copolymers derived from vinyl alcohol and one or more other ethylenically unsaturated polymerizable monomers that contribute to hydrophilicity, including but not limited to acrylic acid and methacrylic acid. Mixtures of different hydrophilic polymers can be used if desired. When crosslinked, the hydrophilic polymers are generally included within the inner layer formulation in an amount of at least 50% and up to and including 95% based on total formulation solids. The inner layer formulation is applied to the anodized aluminum-containing substrate sufficient to provide a crosslinked hydrophilic inner layer dry coverage of at least 0.5 g/m² and up to and including 4 g/m², and typically of at least 1 g/m² and up to and including 2 g/m². The useful hydrophilic binders can be prepared using known starting materials and polymerization conditions and some may be available from commercial sources.

The inner layer formulation also comprises one or more crosslinking agents for the hydroxy groups in the one or more hydrophilic polymers, and at least one of the crosslinking agents comprises at least two aldehyde groups. Such crosslinking agents include but are not limited to, ethane-1,2-dial (also known as ethanedial), butanedial, pentane-1,5-dial, and other dialdehydes. Mixtures of such crosslinking agents can be used. A skilled worker would understand how much crosslinking agent to use based on the amount of hydrophilic polymeric binder to be crosslinked in the inner layer formulation. In general, one or more crosslinking agents are provided in the inner layer formulation in an amount of at least 2 weight % and up to and including 7% based on total hydrophilic polymer binder(s) in the inner layer formulation. Sufficient crosslinking agent is generally present to provide crosslinking at the interface of the crosslinked hydrophilic inner layer and the immediately overlying oleophilic outer layer. Crosslinking of the hydrophilic polymer generally occurs during the drying and heating stages after the layer formulations have been applied to the anodized aluminum-containing substrate. Useful crosslinking agents can be obtained from various commercial sources.

The crosslinked hydrophilic inner layer (and the inner layer formulation used to provide it) also includes one or more acidic compounds such as an inorganic acidic compound including but not limited to phosphoric acid, sulfuric acid, and hydrochloric acid. The acidic compound such as phosphoric acid can be present in the inner layer formulation in an amount of at least 1 weight % and up to and including 5 weight % based on the total inner layer formulation solids (or layer dry weight). Such acidic compounds are readily available from commercial sources.

As noted above, the copolymer described above can be incorporated into the crosslinked hydrophilic inner layer. This can be done by including the copolymer or a solution or dispersion thereof in the inner layer formulation. In general, the copolymer is provided in the inner layer formulation in an amount of at least 2 weight % and up to and including 15 weight %, or typically at least 3 weight % and up to and including 10 weight %, of the dry crosslinked hydrophilic inner layer.

In addition, the crosslinked hydrophilic inner layer can include other addenda that would be useful for coating properties, adhesion to the underlying anodized aluminum-containing substrate, or adhesion to the overlying separate copolymer layer if present. Such addenda can include but are not limited to, silica, alumina, barium sulfate, titanium dioxide, kaolin, or other inorganic particulate materials, and surfactants Infrared radiation absorbers are not purposely incorporated into the crosslinked hydrophilic inner layer, so such compounds are generally not present in the crosslinked hydrophilic inner layer, but some materials may move from the oleophilic outer layer into the crosslinked hydrophilic inner layer.

Oleophilic Outer Layer:

An oleophilic outer layer is provided over the crosslinked hydrophilic inner layer (actually, it may be only partially crosslinked at this point) using an outer layer formulation. This outer layer formulation can be applied while the inner layer formulation is still wet, but more likely it is applied after the inner layer formulation has been at least partially dried.

The outer layer formulation (and oleophilic outer layer) comprises one or more oleophilic polymers that are generally non-crosslinked when applied, such as non-crosslinked oleophilic poly(vinyl acetal) resins comprising at least 10 mol % of randomly recurring units represented by —CH₂CH(OH)—, or at least 15% of randomly recurring acetal units, based on the total recurring units. The one or more oleophilic polymers can be present in the outer layer formulation in an amount of at least 50% and to and including 95% based on total formulation solids.

Each of these oleophilic resins comprises at least 10 mol % randomly recurring units represented by —CH₂—CH(OH)—, and typically at least 20 mol % and up to and including 40 mol % of such recurring units, in random order along the polymer chain, based on the total recurring units in the polymer chain.

The one or more oleophilic resins are generally dissolved in an organic solvent solution that can comprise one or more organic solvents (organic solvent mixture) including but not limited to, methyl ethyl ketone, 2-methoxy-2-propanol, 2-butoxyethanol, dihydrofuan-2(3H)-one (γ-butyrolactone), 1,3-dioxalane, N-methylpyrrolidone, and mixture of two or more of these organic solvents such as a 50:50 or 35:65 volume mixture of methyl ethyl ketone and 1-methoxy-2-propanol. A particularly useful organic solvent solution comprises methyl ethyl ketone and 1-methoxy-2-propanol in a suitable volume ratio. The organic solvent solution is used to apply the outer layer formulation to the crosslinked hydrophilic inner layer.

In addition, each of the one or more oleophilic polymers has a weight average molecular weight (M_{w}) of generally at least 5,000 and up to and including 500,000 and typically at least 10,000 and up to and including 100,000. The optimal M_{w}, can vary with the specific polymer and its use, and can be measured for example, using gel permeation chromatography.

In many embodiments, the randomly recurring acetal units in the non-crosslinked oleophilic poly(vinyl acetal) can be represented by Structure (Ia):

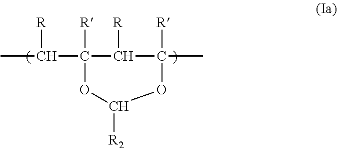

wherein R and R′ are independently hydrogen or a substituted or unsubstituted alkyl group (generally having 1 to 10 carbon atoms), a substituted or unsubstituted cycloalkyl group (having 5 to 10 carbon atoms in the ring structure), or a halo group (such as fluoro, chloro, or bromo).

R₂ can be an aryl group (such as phenyl, naphthyl, or anthryl) that is substituted with a cyclic imide group such as a cyclic aliphatic or aromatic imide group including but not limited to, maleimide, phthalimide, tetrachlorophthalimide, hydroxyphthalimide, carboxypthalimide, nitrophthalimide, chlorophthalimide, bromophthalimide, and naphthalimide groups. The aryl group of the cyclic aliphatic or aromatic imide group, or both the aryl and cyclic aliphatic or aromatic imide groups, are optionally further substituted with one or more substituents selected from the group consisting of hydroxyl, substituted or unsubstituted alkyl, substituted or unsubstituted alkoxy, and halo groups (such as fluoro and chloro), and any other group that does not adversely affect the properties of the cyclic imide group or the poly(vinyl acetal) in the oleophilic surface layer.

Alternatively, R₂ can be a nitro-substituted phenol, nitro-substituted naphthol, or nitro-substituted anthracenol. These groups can also comprise one or more other substituents as described in the previous paragraph.

The non-crosslinked oleophilic poly(vinyl acetal) can also comprise two or more different types of randomly recurring units as defined by Structure (Ia). Thus, such different recurring units can comprise different R₂ groups within the definitions provided above.

Thus, in some embodiments (a), R₂ is a phenyl or naphthyl group that has a cyclic aliphatic or aromatic imide group selected from the group consisting of maleimide, phthalimide, tetrachlorophthalimide, hydroxyphthalimide, carboxypthalimide, nitrophthalimide, chlorophthalimide, bromophthalimide, and naphthalimide groups, wherein the phenyl, naphthyl, or cyclic aliphatic or aromatic imide group is optionally further substituted with one or more substituents selected from the group consisting of hydroxyl, alkyl, alkoxy, and halo groups.

In other embodiments (b), R₂ is a nitro-substituted phenol, nitro-substituted naphthol, or nitro-substituted anthracenol.

In still other embodiments (c), the oleophilic poly(vinyl acetal) comprises a combination of two or more different randomly recurring acetal units represented by Structure (Ia) wherein R₂ represents two or more different groups listed in (a) and (b).

In addition, the non-crosslinked oleophilic poly(vinyl acetal) can further comprise randomly recurring units represented by Structure (Ib):

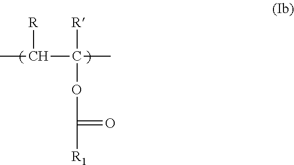

wherein R and R′ are as defined above for Structure (Ia), but they can be same or different groups for these recurring units.

R₁ is a substituted or unsubstituted linear or branched alkyl group having 1 to 12 carbon atoms (such as methyl, ethyl, n-propyl, n-butyl, n-pentyl, n-hexyl, chloromethyl, trichloromethyl, iso-propyl, iso-butyl, t-butyl, iso-pentyl, neo-pentyl, 1-methylbutyl, iso-hexyl, and dodecyl groups), a substituted or unsubstituted cycloalkyl having 5 to 10 carbon atoms in the carbocyclic ring (such as cyclopentyl, cyclohexyl, 4-methylcyclohexyl, and 4-chlorocyclohexyl), or a substituted or unsubstituted aryl group having 6 or 10 carbon atoms in the aromatic ring (such as phenyl, naphthyl, p-methylphenyl, and, p-chlorophenyl). Such groups can be substituted with one or more substituents such as alkyl, alkoxy, and halo, or any other substituent that a skilled worker would readily contemplate that would not adversely affect the performance of the polyvinyl acetal resin in the imagable element.

The non-crosslinked oleophilic poly(vinyl acetal) resins can include randomly recurring units that are selected from one or both of the recurring units represented by the following Structures (Ic) and (Id):

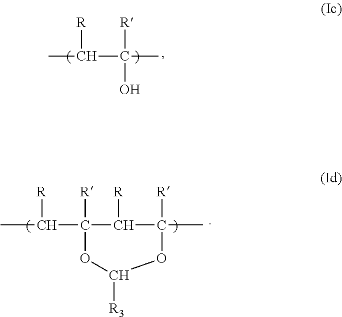

In these Structures, R and R′ are as defined above for Structure (Ia) but each recurring unit need not comprise the same R and R′ group as the other recurring units in the chain.

In Structure (Id), R₃ is hydrogen or a substituted or unsubstituted alkyl group, a substituted or unsubstituted cycloalkyl group, or an aryl group (such as phenyl, naphthyl, or anthracenyl group) that is unsubstituted or substituted with at least one hydroxy group. Thus, R₃ can have one or more hydroxy groups in the ortho, meta, or para positions relative to the aromatic carbon attached to the polymer backbone. The R₃ aryl group can have further substituents such as alkyl, alkoxy, or halo groups that do not adversely affect the properties of the aromatic group or the non-crosslinked oleophilic poly(vinyl acetal).

The non-crosslinked oleophilic poly(vinyl acetal) is generally present in the outer layer formulation (and oleophilic surface layer) in an amount of at least 50% and to and including 95%, and typically at least 60% and up to and including 75%, based on total solids.

When recurring units represented by any combination of Structures (Ia), (Ib), (Ic), and (Id) are present, in random order, the recurring units represented by Structure (Ia) can be present in an amount of at least 10 mol % and up to and including 90 mol %, the recurring units represented by (Tb) can be present in an amount of at least 2 mol % and up to and including 5 mol %, the recurring units represented by Structure (Ic) can be present in an amount of at least 5 mol % and up to and including 45 mol %, and the recurring units represented by Structure (Id) can be present in an amount of at least 2 mol % and up to and including 40 mol %, all based on the total recurring units in the poly(vinyl acetal).

The non-crosslinked poly(vinyl acetal) resins useful in the oleophilic outer layer can comprise at least recurring units represented by Structure (Ia) and recurring units represented by —CH₂—CH(OH)— in any order, and optionally recurring units represented by Structures (Ib) through (Id) but such polymers can also comprise randomly recurring units other than those defined by the illustrated recurring units and such additional recurring units would be readily apparent to a skilled worker in the art. Thus, the polymeric binders useful in the oleophilic outer layer are not limited specifically to the recurring units only defined by Structures (Ia) through (Id).

There also can be multiple types of recurring units from any of the defined classes of recurring units in Structures (Ia), (Ib), and (Id) with different substituents. For example, there can be multiple types of recurring units with different R and R′ groups, and multiple types of recurring units with different R₁, R₂, and R₃ groups. In addition, the number and type of recurring units in the oleophilic polymers are generally in random sequence, but blocks of specific recurring units can also be present unintentionally.

The oleophilic polymers useful in the outer layer formulation (and oleophilic outer layer) can be prepared using known starting materials and reaction conditions. For example, details for preparing useful oleophilic poly(vinyl acetal) resins are provided in WO04/081662 (Memetea et al.) and U.S. Pat. Nos. 6,255,033, 6,541,181, and 7,723,012 (all Levanon et al.) the disclosure of which are incorporated herein by reference. Other useful oleophilic polymers are available from various commercial sources.

Besides the oleophilic poly(vinyl acetal) resins described above, useful oleophilic polymers (including copolymers) include phenolic resins, polyesters, polyvinyl aromatics [such as polystyrenes and poly(hydroxystyrenes)], and mixtures thereof, or mixtures with poly(vinyl acetals), and other oleophilic polymers that exhibit desired adhesion characteristics to the underlying layer(s) and also sufficient chemical resistance to the organic solvents (described below). The best oleophilic outer layer comprises one or more poly(vinyl acetal) resins in an amount of at least 50 weight % of the total oleophilic polymers.

The outer layer formulation (and oleophilic outer layer) can also include other polymeric binders that do not meet the requirements described above as can be identified as “secondary polymeric binders”, as long as the desired properties of the oleophilic outer layer are maintained. These additional polymeric binders include but are not limited to, phenolic resins, including novolak resins such as condensation polymers of phenol and formaldehyde, condensation polymers of m-cresol and formaldehyde, condensation polymers of p-cresol and formaldehyde, condensation polymers of m-/p-mixed cresol and formaldehyde, condensation polymers of phenol, cresol (m-, p-, or m-/p-mixture) and formaldehyde, and condensation copolymers of pyrogallol and acetone. Other useful secondary polymeric binders include nitrocellulose, polyesters, and polystyrenes including poly(hydroxystyrenes).

The oleophilic outer formulation (and oleophilic outer layer) also comprises one or more infrared radiation absorbers that are typically sensitive to near-infrared or infrared radiation and have at least one peak absorption wavelength of at least 700 nm and up to and including 1500 nm and typically of at least 750 nm and up to and including 1400 nm.

Useful infrared radiation absorbers include pigments such as carbon blacks including but not limited to carbon blacks that are surface-functionalized with solubilizing groups are well known in the art. Carbon blacks that are grafted to hydrophilic, nonionic polymers, such as FX-GE-003 (manufactured by Nippon Shokubai), or which are surface-functionalized with anionic groups, such as CAB-O-JET® 200 or CAB-O-JET® 300 (manufactured by the Cabot Corporation) are also useful. Other useful carbon blacks are available from Cabot Billerica under the tradename Mogul. Other useful pigments include, but are not limited to, Heliogen Green, Nigrosine Base, iron (III) oxides, manganese oxide, Prussian Blue, and Paris Blue. The size of the pigment particles should not be more than the thickness of the oleophilic surface.

Examples of suitable IR dyes as infrared radiation absorbers include but are not limited to, azo dyes, squarylium dyes, croconate dyes, triarylamine dyes, thioazolium dyes, indolium dyes, oxonol dyes, oxazolium dyes, cyanine dyes, merocyanine dyes, phthalocyanine dyes, indocyanine dyes, indotricarbocyanine dyes, hemicyanine dyes, streptocyanine dyes, oxatricarbocyanine dyes, thiocyanine dyes, thiatricarbocyanine dyes, merocyanine dyes, ctyptocyanine dyes, naphthalocyanine dyes, polyaniline dyes, polypyrrole dyes, polythiophene dyes, chalcogenopyryloarylidene and bi(chalcogenopyrylo)-polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, polymethine dyes, squarine dyes, oxazole dyes, croconine dyes, porphyrin dyes, and any substituted or ionic form of the preceding dye classes. Suitable dyes are described for example, in U.S. Pat. No. 4,973,572 (DeBoer), U.S. Pat. No. 5,208,135 (Patel et al.), U.S. Pat. No. 5,244,771 (Jandrue Sr. et al.), and U.S. Pat. No. 5,401,618 (Chapman et al.), EP 0 823 327A1 (Nagasaka et al.), and U.S Patent Application Publication 2005-0130059 (Tao).

Near infrared absorbing cyanine dyes are also useful and are described for example in U.S. Pat. No. 6,309,792 (Hauck et al.), U.S. Pat. No. 6,264,920 (Achilefu et al.), U.S. Pat. No. 6,153,356 (Urano et al.), U.S. Pat. No. 5,496,903 (Watanabe et al.), and U.S. Pat. No. 4,973,572 (noted above). Suitable dyes can be formed using conventional methods and starting materials or obtained from various commercial sources including American Dye Source (Baie D'Urfe, Quebec, Canada) and FEW Chemicals (Germany).

The infrared radiation absorbers are generally present in the oleophilic outer layer at a dry coverage of at least 5 weight % and up to and including 50 weight %, or typically in an amount of at least 25 weight % and up to and including 40 weight %, based on the total oleophilic outer layer dry weight. The particular amount needed for this purpose would be readily apparent to one skilled in the art, depending upon the specific compound used. It is particularly useful to use a carbon black in the oleophilic outer layer in an amount of at least 25 weight % and up to and including 35 weight % based on the total dry weight of the oleophilic outer layer.

The oleophilic outer layer can be disposed directly on the crosslinked hydrophilic inner layer. The oleophilic outer layer can be the outermost layer or there can be an overcoat layer disposed on it. In most embodiments, the oleophilic outer layer is the outermost layer of the positive-working lithographic printing plate precursor.

The oleophilic outer layer is generally bonded to the crosslinked hydrophilic inner layer at their interface in a suitable manner. Chemical bonding can be accomplished through crosslinking agents such as those that are included in the inner layer formulation as described above, and particularly ethanedial. Thus, while there can be crosslinking at the interface of the two layers, the oleophilic outer layer is generally non-crosslinked throughout the remainder of its volume. The interface of these two layers can form the composite structure described herein.

The oleophilic outer layer can also include one or more additional compounds that are colorant dyes, or UV or visible light-sensitive components. Useful colorant dyes include triarylmethane dyes such as ethyl violet, crystal violet, malachite green, brilliant green, Victoria blue B, Victoria blue R, and Victoria pure blue BO, BASONYL® Violet 610 and D11 (PCAS, Longjumeau, France). These compounds can act as contrast dyes that distinguish the non-exposed (non-imaged) regions from the exposed (imaged) regions in the lithographic printing plate. When a colorant dye is present in the oleophilic outer layer, its amount can vary widely, but generally it is present in an amount of at least 0.5 weight % and up to and including 30 weight %, based on the total dry weight of the oleophilic outer layer.

The oleophilic outer layer can also include other addenda that would be useful for coating properties, coated layer physical properties, and adhesion to the underlying layer such as small organic molecules, oligomers, and surfactants. These additives can be generally present in the oleophilic outer layer in an amount of at least 1 weight % and up to and including 30 weight %, or typically at least 2 weight % and up to and including 20 weight %, based on total dry weight of the oleophilic outer layer. The oleophilic outer layer can further include a variety of additives including dispersing agents, humectants, biocides, plasticizers, surfactants for coatability or other properties, viscosity builders, fillers and extenders, pH adjusters, drying agents, defoamers, preservatives, antioxidants, rheology modifiers or combinations thereof, or any other addenda commonly used in the lithographic art, in known amounts.

The oleophilic outer layer is generally present at a dry coverage of at least 0.7 g/m² and up to and including 2.5 g/m², and typically at least 1 g/m² and up to and including 1.5 g/m² as provided by the outer layer formulation.

### Preparation of Lithographic Printing Plate Precursors

The positive-working lithographic printing plate precursors can be prepared by applying an inner layer formulation (as described above) in suitable solvents to the surface of the anodized aluminum-containing substrate (or to the applied different copolymer layer if present as described above for some embodiments) using conventional coating or lamination methods. The inner layer formulation can be applied by dispersing or dissolving the desired components (for example hydrophilic polymers, crosslinking agents, acidic compounds, as well as the copolymer described above for some embodiments) in one or more suitable coating solvents. The resulting inner layer formulation can be applied using suitable equipment and procedures, such as spin coating, knife coating, gravure coating, die coating, slot coating, bar coating, wire rod coating, roller coating, or extrusion hopper coating. The inner layer formulation can also be applied by spraying onto a suitable anodized aluminum-containing substrate or different copolymer layer.

The selection of solvents used to coat the inner layer formulation depends upon the nature of its components. Generally, the inner layer formulation is coated out of one or more solvents that can dissolve the hydrophilic polymers including but not limited to, water, water-miscible alcohols, and ketones such as acetone, and mixtures thereof.

The outer oleophilic layer formulation can be prepared by dissolving or dispersing the one or more oleophilic polymers, an infrared radiation absorber, and any optional addenda in suitable organic solvent solution including but not limited to, acetone, methyl ethyl ketone, or another ketone, tetrahydrofuran, 1-methoxy-2-propanol, N-methylpyrrolidone, 1-methoxy-2-propyl acetate, γ-butyrolactone, 1,3-dioxalane, and mixtures thereof using conditions and techniques well known in the art. After application of the outer layer formulation to the dried crosslinked hydrophilic inner layer, the outer layer formulation is also dried.

In some embodiments, the resulting lithographic printing plate precursor can be further heated immediately after the drying of the outer layer formulation or at a later stage. Layer drying and the optional additional heating process encourage adhesion (and crosslinking) of the oleophilic outer layer to the crosslinked hydrophilic inner layer to form the composite structure consisting of at least parts of both layers.

Representative methods for preparing positive-working imagable elements are described below in the examples. For example, after all of the layer formulations are dried on the anodized aluminum-containing substrate (that is, the coatings are dry to the touch), the lithographic printing plate precursor can be heated to facilitate adhesion especially between the oleophilic outer layer and the crosslinked hydrophilic inner layer. Alternatively, this heating (generally using higher temperatures than used in the drying step) can be combined with the drying step into a single drying/heating step at a high enough temperature to obtain desired adhesion between the noted layers.

This heating can be carried out in a variety of ways as described below such that upon heating the formed composite structure and in particular the oleophilic outer layer, exhibits less than 10% optical density change within a first rectangular area defined by width W1 and length L1 centered inside a second rectangular area defined by width W2 and length L2, where the surface of the composite structure is subjected to 1000 rubs according to ASTM D3181 using the organic solvent solution used to coat or apply the oleophilic outer layer formulation, wherein W1 is 0.7 times W2, L1 is 0.7 times L2, W2 is 1.5 cm, and L2 is 12 cm. In particular, upon the heat treatment, the composite structure exhibits less than 10% (preferred) optical density change within the first rectangular area.

Optical density change can be measured by using a densitometer such as a Spectropens (available from Techkon, Germany).

ASTM D3181 is a standard guide for conducting wear test on textiles that was adapted for testing the relative adhesion strengths of the outer oleophilic layer (formulation) to the crosslinked inner hydrophilic layer in the lithographic printing plate precursors. This test generally includes determining the comparative performance of a precursor after it has been rubbed for a given number of times. This can be carried out conveniently with a Crockmeter and the level of wear that is observed can be evaluated with the unaided eye or in a more quantitative way, such as using a densitometer, as described below in the rubbing tests section.

In these rubbing tests, a sample of a lithographic printing plate precursor is placed in a Crockmeter that has a “finger” that is wrapped with a cloth soaked with a solvent (for example a PM/MEK mixture shown in the Invention Examples below). This wrapped “finger” moves back and forth across the surface of the precursor for a given number of times causing wear to the oleophilic outer layer.

Some specific heating protocols to achieve the desired adhesion of the layers in the precursor are as follows:

1. After drying the lithographic printing plate precursor for 1 minute at 100° C., it is then further heated for 75 seconds at 240° C. in a suitable oven. An example of a useful oven is a Wisconsin oven.

2. Drying and heating the lithographic printing plate precursor in one step for 75 seconds at 240° C. in a suitable oven (such as in a Wisconsin oven).

3. After drying the lithographic printing plate precursor, it is then further heated for 2 seconds with a short wave IR lamp that can generate suitable irradiation power. A useful example of this process is the use of the short wave IR lamp that can generate up to 75 W/cm and that was operated such that it irradiated at 70% of its maximum power. The IR lamp can be placed 9.5 cm above the precursor but a combination of distance and irradiation power can be adjusted as needed.

While these three procedures are particularly useful, a skilled worker in the art would be able to use the teaching provided in this disclosure to carry out other suitable drying, heating, or drying/heating procedures to achieve the desired results in the precursors of the present invention.

The lithographic printing plate precursors of this invention can be stored or shipped to a user in appropriate containers as stacks of multiple precursors, such as at least 10 precursors or even at least 50 precursors and up to 1000 precursors. A suitable interleaf sheet can be provided between adjacent precursors as well as between the topmost precursor in the stack and the outer packaging material. Such interleaf sheets can have the same or different coefficient of friction values on opposing sides.

### Imaging and Printing

The lithographic printing plate precursors of the present invention are useful for forming lithographic printing plates. The lithographic printing plate precursors can be of any useful size and shape (for example, square or rectangular) having the requisite layers disposed on a suitable anodized aluminum-containing substrate.

During use, the lithographic printing plate precursors are exposed to a suitable source of radiation such as near-IR and infrared radiation, depending upon the infrared radiation absorber that is present in the oleophilic outer layer, for example at a wavelength of at least 700 and up to and including 1500 nm. This exposure ablates the oleophilic outer layer to provide exposed regions to prepare a lithographic printing plate ready for printing without further treatment or processing.

For most embodiments, imaging is carried out using an infrared or near-infrared laser at a wavelength of at least 700 and up to and including 1200 nm. The laser used to expose the precursor can be a diode laser, because of the reliability and low maintenance of diode laser systems, but other lasers such as gas or solid-state lasers may also be used. The combination of power, intensity and exposure time for laser imaging would be readily apparent to one skilled in the art.

The imaging apparatus can function solely as a platesetter or it can be incorporated directly into a lithographic printing press. Printing can commence immediately after imaging without intermediate contact with any solutions. The imaging apparatus can be configured as a flatbed recorder or as a drum recorder, with the lithographic printing plate precursor mounted to the interior or exterior cylindrical surface of the drum. A useful imaging apparatus is available as models of Kodak Trendsetter imagesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm (available from Gerber Scientific, Chicago, Ill.) and the Screen PlateRite 4300 series or 8600 series platesetter (available from Screen, Chicago, Ill.). Additional useful sources of radiation include direct imaging presses that can be used to image a precursor while it is attached to the printing plate cylinder. An example of a suitable direct imaging printing press includes the Heidelberg SM74-DI press (available from Heidelberg, Dayton, Ohio).

In some embodiments, the infrared radiation exposure energy can be at least 1 J/cm², or typically of at least 1 J/cm² and up to and including 4 J/cm², but higher imaging energies are also possible.

While laser imaging is usually practiced, imaging can be provided by any other means that provides thermal energy in an imagewise fashion. For example, imaging can be accomplished using a thermoresistive head (thermal printing head) in what is known as “thermal printing”, described for example in U.S. Pat. No. 5,488,025 (Martin et al.). Thermal print heads are commercially available (for example, as Fujitsu Thermal Head FTP-040 MCS001 and TDK Thermal Head F415 HH7-1089).

Imaging is generally carried out using direct digital imaging. The image signals are stored as a bitmap data file on a computer. Such data files may be generated by a raster image processor (RIP) or other suitable means. The bitmaps are constructed to define the hue of the color as well as screen frequencies and angles.

Imagewise exposure of the lithographic printing plate precursor produces a latent image of imaged or exposed (ablated) and non-imaged or non-exposed (non-ablated) regions. Substantially the entire oleophilic outer layer and perhaps a small portion of the crosslinked hydrophilic inner layer are ablated or physically removed in the imaged or exposed regions.

The ablated material from exposed regions in the one or more layers can be removed from the imaged lithographic printing plate precursor using known means such as vacuum, or wiping with a dry or moist cloth (for example, dry cleaning) before the imaged precursor is used for printing. In particular, the imaged precursor can be dry cleaned before being used for lithographic printing. In other embodiments, the imaged precursor is used for lithographic printing without dry cleaning and without intermediate contact with any solution. An important aspect of this invention is that wet processing such as development with water or a developer solution, gumming, or water rinsing is not required before the imaged precursor is used for lithographic printing. Thus, it is an important advantage that lithographic printing can be carried out immediately after the lithographic printing plate precursor is imaged by ablation.

During the practice of the method of the present invention, ablation so completely removes the oleophilic outer layer that very little debris (trace amounts) in the form of very small particles are left due to electrostatic attraction to the oleophilic outer surface of the lithographic printing plate. These small particles can be removed during printing by the fountain solution and lithographic printing ink. The background in printed images is very clear at the beginning of the print run. Thus, with the present invention, it is possible to achieve literally processless lithographic printing plates using ablation for imaging.

The imaged lithographic printing plates of this invention can be used for lithographic printing on any suitable printing apparatus using known fountain solutions and lithographic printing inks. The lithographic printing plate can be used in a single printing run for its entire printing life, or printing can be stopped and the printing plate can be cleaned before resuming lithographic printing.

The present invention provides at least the following embodiments and combinations thereof, but other combinations of features are considered to be within the present invention as a skilled artisan would appreciate from the teaching of this disclosure:

The following Examples are provided to illustrate the practice of this invention and are not meant to be limiting in any manner. In these examples, the following components were used to prepare the lithographic printing plate precursors. Unless otherwise indicated, the components are available from Aldrich Chemical Company (Milwaukee, Wis.):

BF-03 represents a poly(vinyl alcohol), 98% hydrolyzed (Mw=15,000) that was obtained from Chang Chun Petrochemical Co. Ltd. (Taiwan).

Celvol® 125 is a poly(vinyl alcohol), 99.3% hydrolyzed, average molecular weight 124,000 that can be obtained from Celanese Chemicals.

DMSO represents dimethylsulfoxide.

The Glyoxal solution was a 40 weight % solution of ethanedial in water (available from Sigma Aldrich Company).

MEK represents methyl ethyl ketone.

Mogul® L is a carbon black powder that can be obtained from Cabot Billerica.

MSA represents methanesulfonic acid (99%, Sigma Aldrich Company).

PM represents 1-methoxy-2-propanol, can be obtained as Arcosolv® PM (Lyondell).

TEA represents triethanolamine.

VP11 represents a copolymer derived from acrylamide and vinyl phosphonic acid, with randomly distributed recurring units at a molar ratio of 9:1, acrylamides to vinyl phosphonic acid.

A carboxy-substituted 4-phthalimidobenzaldehyde, IUPAC name 2-(4-formylphenyl)-1,3-dioxoisoindoline-5-carboxylic acid (Compound I) was prepared as follows:

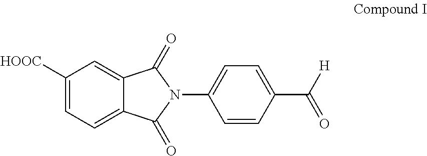 [SMILES: O=Cc1ccc(N2C(=O)c3ccc(C(=O)O)cc3C2=O)cc1]

4-Aminobenzaldehyde (10 g) and 1,2,4-benzenetricarboxylic anhydride (15.86 g) were added to a 500 ml round bottom glass vessel equipped with a magnetic stirrer. Then, 350 g of acetic acid was added to the reaction vessel. The mixture was heated to the reflux while being stirred for 8 hours. The reaction mixture was chilled to room temperature. The precipitated product was filtered off, washed on the filter with water and alcohol, and dried. The yield of Compound I was 80% with mp of 317° C.

Preparation of Polymer MN-24:

BF-03 polyvinyl alcohol (10.14 g) was added to a reaction vessel fitted with a water-cooled condenser, a dropping funnel and thermometer, containing DMSO (140 g). With continual stirring, the mixture was heated for 30 minutes at 80° C. until it became a clear solution. The temperature was then adjusted to 60° C. and MSA (0.88 g) was added. 2-(4-Formylphenyl)-1,3-dioxoisoindoline-5-carboxylic acid (10.00 g) in DMSO (20 g) was added to the reaction mixture that was kept for 150 minutes at 85° C. Then, 2-hydroxy-5-nitro benzaldehyde (5-nitro-salicylic aldehyde, 8.87 g) and DMSO (20 g) were added to the reaction mixture and it was kept for 1 hour at 85° C. The resulting reaction mixture was then diluted with DMSO (40 g) and anisole (55 g), and vacuum distillation was started. The anisole:water azeotrope was distilled out from the reaction mixture (less than 0.1% of water remained in the solution). The reaction mixture was then chilled to room temperature, neutralized with TEA (1 g) dissolved in DMSO (90 g), and blended with 1.8 kg of water. The resulting precipitated polymer was washed with water, filtered and dried in vacuum for 24 hours at 60° C. to obtain 25.2 g of dry Polymer MN-24.

The following Scheme 1 shows the recurring units in Pol-PM-24 that was derived from polyvinyl alcohol having 2% original acetate and its free OH groups were converted to acetals of carboxy substituted 4-phthalimido-benzaldehyde and 5-nitrosalicylic aldehyde at 30% and 47%, respectively.

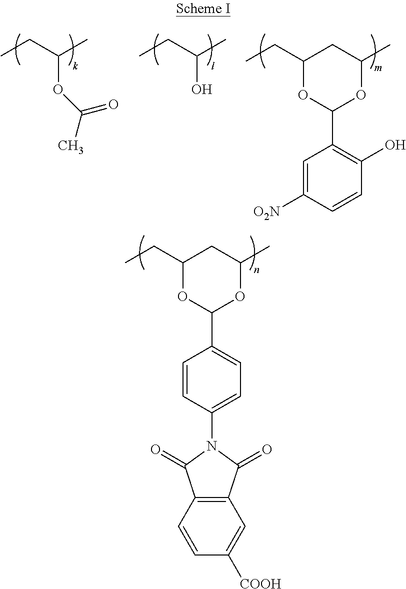

The print run lengths obtained using the various Invention Example positive-working ablation-imagable lithographic printing plate precursors tested and described herein were compared to that obtained using the precursor described in Comparative Example 1, and which comprises a grained and phosphoric anodized aluminum substrate that was not treated with a copolymer according to the present invention. The precursor of Comparative Example 1 served as a “standard” plate in the printing tests described below. Thus, the print run lengths described in the Invention Examples below are reported in relation (%) to the print run length obtained with the “standard” prior art precursor of Comparative Example 1.

### Invention Example 1

Positive-working ablation-imagable lithographic printing plate precursors of the present invention were prepared by the following procedure. A hydrophilic inner layer formulation was prepared from the following components.

| Hydrophilic Inner Layer | | |
|---|---|---|
| Formulation | Weight (g) | Dry Weight % |
| Celvol ® 125* | 57.275 | 90.67 |
| Glyoxal solution** | 0.337 | 5.33 |
| Phosphoric acid solution*** | 0.119 | 4.0 |
| Water | 2.269 | 0 |

*4 weight % of PVA in water
**40 weight % of Glyoxal in water
***85 weight % of phosphoric acid in water

The hydrophilic inner layer formulation was applied to an electrochemically roughened and sulfuric acid anodized aluminum substrate that had been post-treated using an aqueous solution of VP11 copolymer, and dried for 1 minute at 120° C. in an oven. The dry coating weight of the resulting crosslinked hydrophilic inner layer was about 1.7 g/m².

Onto this dried crosslinked hydrophilic inner layer was coated an oleophilic outer layer formulation that was prepared by milling for 3 days (with metal balls) the following components (of Part A) that were then diluted with the solvent mixture part B.

| | | Dry Weight |
|---|---|---|
| Oleophilic Outer Layer Formulation | Weight (g) | (%) |
| Part A - Milled base | | |
| Polymer MN-24 | 4.053 | 65 |
| MEK | 8.709 | 0 |
| PM | 16.175 | 0 |
| Mogul L | 2.182 | 35 |
| Part B - Solvents added to Part A after milling | | |
| MEK | 7.911 | 0 |
| PM | 14.692 | 0 |

The applied oleophilic outer layer formulation was dried for 1 minute at 100° C. in an oven. The resulting precursor was further heated for 75 seconds at 240° C. in an oven to provide an oleophilic outer layer dry coating coverage of about 1.4 g/m².

A sample of the precursor was exposed at 1500 mJ/cm² using a Kodak® Lotem 400 Quantum imager (having 1 bar of diodes, 224 valves and overall intensity of 25 Watt). The imaged precursor was gently wet cleaned with water, removing the black material left on the imaged background to provide a lithographic printing plate. The lithographic printing plate of Invention Example 1 and that of Comparative Example 1 (described below) were then mounted together on a Ryobi 520HX printing press so that their print run lengths could be compared in the same printing test. The number of impressions needed to reach a wear of more than 20% reduction in printed dots size of fine features (2 and 5% dots at 200 lpi screen) was used to compare the print performance of the lithographic printing plates.

Both lithographic printing plates showed good image quality and the lithographic printing plate of Invention Example 1 showed a print run length of 100% (for 2% dots at 200 lpi screen) and 125% (for 5% dots at 200 lpi screen), compared to the printing results obtained with the “standard” lithographic printing plate of Comparative Example 1.

A white printed background was obtained, corresponding to a fully imaged area on the printing plate. This was observed from the beginning of the print test. On the other hand, when a sample of the imaged Invention Example 1 precursor was mounted on-press without first water cleaning it, the white printed background was obtained only after about 50 impressions, that is the black material left on the imaged background was removed on-press and the imaged precursor was developed on-press. However, when a sample of the Invention Example 1 precursor was imaged using a more powerful laser of a Kodak® Thermo Flex 400 imager (having 48 diodes of 1 Watt each), the imaged areas on the imaged precursor were almost completely clean (only trace amounts of debris left in the imaged background). In this case, the imaged precursor was not cleaned after imaging and the trace amounts of debris left on the printing plate were easily removed by the fountain solution on-press. Fully imaged areas that were not cleaned printed a white background as observed from the beginning of the print test. Therefore, in this invention, it was possible to achieve literally processless lithographic printing plates by ablation imaging.

In addition, the lithographic printing plate of Invention Example 1 exhibited a much improved print run length compared to that of Comparative Example 2 (described below). This suggests that subjecting the surface of the sulfuric acid anodized aluminum substrate to a treatment using an aqueous solution of the VP11 copolymer (as in Invention Example 1) led to a much better image adhesion compared to that obtained when the sulfuric acid anodized aluminum substrate was not further treated with the VP11 copolymer as in Comparative Example 2.

Furthermore, while a good print run length was obtained with the lithographic printing plate of Comparative Example 1, which comprises a relatively expensive phosphoric acid anodized aluminum substrate, the use of the VP11 copolymer in the lithographic printing plate of Invention Example 1 allowed for a good print run length that was similar to that obtained with the lithographic printing plate of Comparative Example 1, using a less expensive sulfuric acid anodized aluminum substrate.

Without being bound to a particular mechanism or explanation, the improved print run length obtained with the lithographic printing plate of Comparative Example 1 compared to that obtained with the lithographic printing plate of Comparative Example 2 could be due to the very different topography of the two different anodized aluminum substrates that were observed in scanning electron micrographs of the two substrates. In contrast to the sulfuric acid anodized aluminum substrate used in Comparative Example 2, the phosphoric acid anodized aluminum substrate used in Comparative Example 1 had hollow deep channels going through the anodic oxide surface of the aluminum. It could be that the hydrophilic inner layer formulation (comprising Celvol® 125, Glyoxal, and phosphoric acid) was able to better penetrate into the phosphoric acid anodized aluminum anodic surface, thus improving the adhesion of the resulting crosslinked hydrophilic inner layer to the substrate and also improving the resulting image adhesion, leading to a much improved print run length.

In addition, without being bound to a particular mechanism or explanation, the improved print run length obtained with the lithographic printing plate of Invention Example 1 compared to that obtained with the lithographic printing plate of Comparative Example 2 could be due to a reaction of the amide-containing recurring units of the VP11 copolymer with the hydroxyl groups of the polyvinyl alcohol used in the crosslinked hydrophilic inner layer and a reaction of the phosphoric acid-containing recurring units of the VP11 copolymer with the surface of the anodized aluminum substrate, enhancing the adhesion of the crosslinked hydrophilic inner layer to the substrate and hence increasing image adhesion and the print run length.

### Comparative Example 1

Lithographic printing plate precursors outside the present invention were prepared using the same general procedure described above for Invention Example 1, but an electrochemically roughened and phosphoric acid anodized aluminum substrate that was not treated with an aqueous solution of the VP11 copolymer, was used.

The resulting precursor was exposed at 1500 mJ/cm² using a Kodak® Lotem 400 Quantum imager (having 1 bar of diodes, 224 valves and overall intensity of 25 Watt). The imaged precursor was gently wet cleaned with water, removing the black material still left on the imaged background. The imaged precursor was then mounted on a Ryobi 520HX printing press and 210,000 impressions were made showing good image quality. Wear of more than 20% reduction in printed dots size of fine features was seen only after about 200,000 impressions (for 2% dots at 200 lpi screen) and after more than 210,000 impressions (for 5% dots at 200 lpi screen). A white printed background was obtained, corresponding to a fully imaged area on the lithographic printing plate, as observed from the beginning of the printing test.

On the other hand, when the imaged precursor was mounted onto a printing press without first water cleaning, the white printed background was obtained only after about 50 impressions. This, the black material left on the imaged background was removed on-press during printing and the imaged precursor was developed on-press.

However, when a sample of the lithographic printing plate precursor was imaged using a more powerful laser of a Kodak® Thermo Flex 400 imager (having 48 diodes of 1 Watt each), the imaged areas on the precursor were almost completely clean after imaging (only trace amounts of debris left in the imaged background). In this ease, the imaged precursor was not cleaned after imaging and the trace amounts of debris left after imaging were easily removed by the fountain solution during printing on-press. Fully imaged areas that were not cleaned printed white background and this was observed from the beginning of the printing test. In this case it was possible to achieve literally processless printing plates by ablation imaging.

### Comparative Example 2

Lithographic printing plate precursors outside the present invention were prepared using the same general procedure described above for Invention Example 1, but this time an electrochemically roughened and sulfuric acid anodized aluminum substrate that was not treated with an aqueous solution of the VP11 copolymer.

The imaged precursor was exposed at 1500 mJ/cm² using a Kodak® Lotem 400 Quantum imager (having 1 bar of diodes, 224 valves and overall intensity of 25 Watt). The imaged precursor was gently wet cleaned with water, removing the black material still left on the imaged background. The imaged precursors of Comparative Example 2 and Comparative Example 1 were then mounted together on a Ryobi 520HX printing press so that their print run length could be compared in the same printing test. The number of impressions needed to reach a wear of more than 20% reduction in printed dots size of fine features (2 and 5% dots at 200 lpi screen) was used to compare the print performance of the various lithographic printing plates used.

Both lithographic printing plates showed good image quality and the lithographic printing plate of Comparative Example 2 showed a print run length of 30% (for 2% dots at 200 lpi screen) and 38% (for 5% dots at 200 lpi screen) compared to that obtained with the standard lithographic printing plate of Comparative Example 1.

On the other hand, when a sample of the imaged precursor was mounted onto a printing press without first water cleaning, the white printed background was obtained only after about 50 impressions. That is, the black material left on the imaged background was removed on-press during printing and in this case the imaged precursor was developed on-press.

However, when a sample of the lithographic printing plate precursor was imaged using a more powerful laser of a Kodak® Thermo Flex 400 imager (having 48 diodes of 1 Watt each), the imaged areas on the precursor were almost completely clean after imaging (only trace amounts of debris left in the imaged background). In this case, the imaged precursor was not cleaned after imaging and the trace amounts of debris left after imaging were easily removed by the fountain solution during printing on-press. Fully imaged areas that were not cleaned printed white background, as observed from the beginning of the printing test. Therefore, it was possible to achieve literally processless printing plates by ablation imaging.

### Invention Example 2

Lithographic printing plate precursors were prepared using the same general procedure described above for Invention Example 1, but the VP11 copolymer was incorporated within the hydrophilic inner layer formulation that was applied to an electrochemically roughened and sulfuric acid anodized aluminum substrate that was not subjected to an additional post-treatment with an aqueous solution of the VP 11 copolymer. In this case, the hydrophilic inner layer formulation was prepared from the following components:

| Hydrophilic Inner Layer Formulation | Weight (g) | Dry Weight % |
|---|---|---|
| Celvol ® 125* | 32.691 | 88.77 |
| Glyoxal solution** | 0.192 | 5.23 |
| Phosphoric acid solution*** | 0.069 | 4.0 |
| VP-11 Copolymer**** | 0.590 | 2.0 |
| Water | 1.457 | 0 |

*4 weight % of PVA in water
**40 weight % of Glyoxal in water
***85 weight % of phosphoric acid in water
****5 weight % of VP-11 in water

As in Invention Example 1, the hydrophilic inner layer formulation was dried for 1 minute at 120° C. in an oven and the dry coating coverage of the crosslinked hydrophilic inner layer was about 1.7 g/m². The oleophilic outer layer formulation described in Invention Example 1 was applied to the dry crosslinked hydrophilic inner layer to provide the dry oleophilic outer layer coverage as described above.

A sample of the resulting lithographic printing plate precursor was exposed at 1500 mJ/cm² with a Kodak® Lotem 400 Quantum imager (having 1 bar of diodes, 224 valves and overall intensity of 25 Watt). The imaged precursor was gently wet cleaned with water, removing the black material still left on the imaged background. The imaged precursors of Invention Example 2 and Comparative Examples 1 and 2 were then mounted together on a Ryobi 520HX printing press so that their print run lengths could be compared in the same printing test. The number of impressions needed to reach a wear of more than 20% reduction in printed dots size of fine features (2 and 5% dots at 200 lpi screen) was used to compare the print performance of the various lithographic printing plates used.

The three lithographic printing plates showed good image quality and the lithographic printing plate of Invention Example 2 showed a print run length of 40% (for 2% dots at 200 lpi screen) and 54% (for 5% dots at 200 lpi screen) compared to that obtained with the lithographic printing plate of Comparative Example 1.

A white printed background was obtained, corresponding to a fully imaged area on the lithographic printing plate. This was observed already from the beginning of the print test. On the other hand, when a sample of the imaged Invention Example 2 precursor was mounted on-press without first water cleaning it, the white printed background was obtained only after about 50 impressions that is, the black material left on the imaged background was removed on-press and so the imaged precursor was developed on-press.

However, when a sample of the Invention Example 2 precursor was imaged with a more powerful laser of a Kodak® Thermo Flex 400 imager (having 48 diodes of 1 Watt each), the imaged areas on the precursor were almost completely clean after imaging (only trace amounts of debris left in the imaged background). In this case, the imaged precursor was not cleaned after imaging and the trace amounts of debris left on the imaged precursor were easily removed by the fountain solution on-press. Indeed, fully imaged areas that were not cleaned printed white background, and this was observed from the beginning of the print test. Therefore, it was possible to achieve literally processless printing plates by ablation imaging.

In addition, the lithographic printing plate of Invention Example 2 exhibited an improved print run length compared to that described in Comparative Example 2. This suggests that adding the VP11 copolymer to the crosslinked hydrophilic inner layer improved the image adhesion and print run length even without subjecting the surface of the sulfuric acid anodized aluminum substrate to a treatment using the VP 11 copolymer.

While improved print run length was demonstrated with the lithographic printing plate of Invention Example 2, compared to that obtained with the lithographic printing plate of Comparative Example 2, there was a need to further improve the long print run length using the VP11 copolymer.

### Invention Example 3

Lithographic printing plate precursors were prepared using the same general procedure described above for Invention Example 2, but an increased amount of the VP11 copolymer was incorporated into the crosslinked hydrophilic inner layer. The hydrophilic inner layer formulation was prepared from the following components.

| Hydrophilic Inner Layer Formulation | Weight (g) | Dry Weight % |
|---|---|---|
| Celvol ® 125* | 32.349 | 87.83 |
| Glyoxal solution** | 0.190 | 5.17 |
| Phosphoric acid solution*** | 0.069 | 4.0 |
| VP-11 Copolymer**** | 0.885 | 3.0 |
| Water | 1.506 | 0 |

*4 weight % of PVA in water
**40 weight % of Glyoxal in water
***85 weight % of phosphoric acid in water
****5 weight % of VP-11 in water

As in Invention Example 2, the hydrophilic inner layer formulation was applied to an electrochemically roughened and sulfuric acid anodized aluminum substrate that was not treated with the VP11 copolymer and the hydrophilic inner layer coating was dried for 1 minute at 120° C. in an oven. The dry coating coverage of the crosslinked hydrophilic inner layer was about 1.7 g/m².

An oleophilic outer layer formulation was applied to the dry crosslinked hydrophilic inner layer as described in Invention Example 1.

The resulting precursor was exposed at 1500 mJ/cm² with a Kodak® Lotem 400 Quantum imager (having 1 bar of diodes, 224 valves and overall intensity of 25 Watt). The imaged precursor was gently wet cleaned with water, removing the black material still left on the imaged background. The imaged precursors of Invention Example 3 and Comparative Examples 1 and 2 were then mounted together on a Ryobi 520HX printing press so that their print run length could be compared in the same printing test. The number of impressions needed to reach a wear of more than 20% reduction in printed dots size of fine features (2 and 5% dots at 200 lpi screen) was used to compare the print performance of the various printing plates.

The three lithographic printing plates showed good image quality and the lithographic printing plate of Invention Example 3 showed a print run length of 50% (for 2% dots at 200 lpi screen) and 69% (for 5% dots at 200 lpi screen) compared to that obtained with the lithographic printing plate of Comparative Example 1.

A white printed background was obtained, corresponding to a fully imaged area on the printing plate. This was observed from the beginning of the print test. On the other hand, when a sample of the imaged Invention Example 3 precursor was mounted on-press without first water cleaning it, the white printed background was obtained only after about 50 impressions, that is the black material left on the imaged background was removed on-press and so in this case the imaged precursor was developed on-press. However, when the Invention Example 3 precursor was imaged with a more powerful laser of a Kodak® Thermo Flex 400 imager (having 48 diodes of 1 Watt each), the imaged areas were almost completely clean after imaging (only trace amounts of debris left in the imaged background). In this case, the imaged precursor was not cleaned after imaging and the trace amounts of debris left on the imaged precursor were easily removed by the fountain solution on-press. Indeed, fully imaged areas that were not cleaned printed white background and this was observed from the beginning of the print test. Therefore, it was possible to achieve literally processless printing plates by ablation imaging.

In addition, the lithographic printing plate of Invention Example 3 exhibited an improved print run length compared to that described in Comparative Example 2. This suggests that incorporating the VP 11 copolymer into the hydrophilic inner layer improved the image adhesion and print run length even without subjecting the surface of the sulfuric acid anodized aluminum substrate to a treatment of the VP 11 copolymer. Furthermore, the lithographic printing plate of Invention Example 3 exhibited an improved print run length compared to that described in Invention Example 2. This shows that using an increased amount of the VP11 copolymer in the crosslinked hydrophilic inner layer provided improved print run length.

While improved print run length was demonstrated with the lithographic printing plate of Invention Example 3, compared to that obtained with the lithographic printing plate of Comparative Example 2, the amount of the VP11 copolymer used in Invention example 3 did not provide a long print run length as obtained with the lithographic printing plate of Comparative Example 1.

### Invention Example 4

Lithographic printing plate precursors were prepared using the same general procedure described above for Invention Example 3, but an increased amount of the VP 11 copolymer was added to the crosslinked hydrophilic inner layer. The hydrophilic inner layer formulation was prepared from the following components:

| | | Dry Weight |
|---|---|---|
| Hydrophilic Inner Layer Formulation | Weight (g) | (%) |
| Celvol ® 125* | 31.623 | 85.95 |
| Glyoxal solution** | 0.186 | 5.05 |
| Phosphoric acid solution*** | 0.069 | 4.0 |
| VP-11 Copolymer***** | 1.472 | 7.0 |
| Water | 1.650 | 0 |

*4 weight % of PVA in water
**40 weight % of Glyoxal in water
***85 weight % of phosphoric acid in water
****5 weight % of VP-11 in water

As in Invention Example 3, the hydrophilic inner layer formulation was applied to an electrochemically roughened and sulfuric anodized aluminum substrate that was not subjected to a treatment of the VP11 copolymer, and the coated hydrophilic inner layer formulation was dried for 1 minute at 120° C. in an oven. The dry coverage of the crosslinked hydrophilic inner layer was about 1.7 g/m². The oleophilic outer layer formulation was applied to the crosslinked hydrophilic inner layer as described in Invention Example 3.

The resulting lithographic printing plate precursors were exposed at 1500 mJ/cm² using a Kodak® Lotem 400 Quantum imager (having 1 bar of diodes, 224 valves and overall intensity of 25 Watt). A sample of the imaged precursors was gently wet cleaned with water, removing the black material still left on the imaged background. The imaged precursors of Invention Example 4 and Comparative Examples 1 and 2 were then mounted together on a Ryobi 520HX printing press so that their print run length could be compared in the same printing test. The number of impressions needed to reach a wear of more than 20% reduction in printed dots size of fine features (2 and 5% dots at 200 lpi screen) was used to compare the print performance of the various lithographic printing plates used. All three lithographic printing plates showed good image quality and the lithographic printing plate of Invention Example 4 showed a print run length of 110% (for 2% dots at 200 lpi screen) and >108% (for 5% dots at 200 lpi screen), of that obtained with the lithographic printing plate of Comparative Example 1.

A white printed background was obtained, corresponding to a fully imaged area on the lithographic printing plate. This was observed from the beginning of the print test. On the other hand, when another sample of the imaged precursor of the present invention was mounted on-press without first water cleaning it, the white printed background was obtained only after about 50 impressions. That is, the black material left on the imaged background was removed on-press and the imaged precursor was developed on-press. However, when another sample of the precursor of the present invention was imaged using a more powerful laser of a Kodak® Thermo Flex 400 imager (having 48 diodes of 1 Watt each), the imaged areas on the precursor were almost completely clean after imaging (only trace amounts of debris left in the imaged background). In this case, the imaged precursor was not cleaned after imaging and the trace amounts of debris left on the printing plate after imaging were easily removed by the fountain solution on-press. Indeed, fully imaged areas that were not cleaned printed white background, and this was observed from the beginning of the print test. In this case, it was possible to achieve literally processless plates by ablation.

In addition, the lithographic printing plate of Invention Example 4 exhibited a much improved print run length compared to that described in Comparative Example 2. This suggests that adding the VP11 copolymer to the crosslinked hydrophilic inner layer improved the image adhesion and print run length even without subjecting the surface of the sulfuric anodized aluminum substrate to a treatment of the VP11 copolymer. Furthermore, the printing plate of Invention Example 4 exhibited an improved print run length compared to that described in Invention Example 3. This shows that using an increased amount of the VP11 copolymer in the crosslinked hydrophilic inner layer provided improved print run length.

At the level of the VP11 copolymer used in Invention Example 4, it is possible to obtain a print run length similar to that obtained with the lithographic printing plate of Comparative Example 1.

### Invention Example 5

Lithographic printing plate precursors of the present invention were prepared using the same general procedure described above for Invention Example 4, but an increased amount of the VP11 copolymer was added to the crosslinked hydrophilic inner layer. The hydrophilic inner layer formulation was prepared from the following components:

| | | Dry Weight |
|---|---|---|
| Hydrophilic Inner Layer Formulation | Weight (g) | (%) |
| Celvol ® 125* | 30.950 | 84.05 |
| Glyoxal solution** | 0.182 | 4.95 |
| Phosphoric acid solution*** | 0.069 | 4.0 |
| VP-11 Copolymer***** | 2.061 | 7.0 |
| Water | 1.737 | 0 |

*4 weight % of PVA in water
**40 weight % of Glyoxal in water
***85 weight % of phosphoric acid in water
****5 weight % of VP-11 in water

As described for Invention Example 4, the hydrophilic inner layer formulation was applied to an electrochemically roughened and sulfuric anodized aluminum substrate that was not subjected to an additional chemical after treatment with an aqueous solution of the VP11 co-polymer and the coating dried for 1 minute at 120° C. in an oven. The weight of the hydrophilic inner layer was approx. 1.7 g/m².

A sample of the lithographic printing plate precursors was exposed at 1500 mJ/cm² using a Kodak® Lotem 400 Quantum imager (having 1 bar of diodes, 224 valves and overall intensity of 25 Watt). The imaged precursor was gently wet cleaned with water, removing the black material still left on the imaged background. The imaged precursors of Invention Example 5 and Comparative Example 1 were then mounted together on a Ryobi 520HX printing press so that their print run length could be compared in the same printing test. The number of impressions needed to reach a wear of more than 20% reduction in printed dots size of fine features (2 and 5% dots at 200 lpi screen) was used to compare the print performance of the various lithographic printing plates. Both lithographic printing plates showed good image quality and the lithographic printing plate of Invention Example 5 showed a print run length of 150% (for 2% dots at 200 lpi screen) and 150% (for 5% dots at 200 lpi screen) of that obtained with the lithographic printing plate of Comparative Example 1.

A white printed background was obtained, corresponding to a fully imaged area on the printing plate as observed already from the beginning of the print test. On the other hand, when a sample of the imaged Invention Example 5 precursor was mounted on-press without first water cleaning it, the white printed background was obtained only after about 50 impressions, that is the black material left on the imaged background was removed on-press and in this case the imaged precursor was developed on-press. However, when a sample of the Invention Example 5 precursor was imaged using a more powerful laser of a Kodak® Thermo Flex 400 imager (having 48 diodes of 1 Watt each), the imaged areas on the imaged precursor were almost completely clean after imaging (only trace amounts of debris left in the imaged background). In this case, the precursor was not cleaned after imaging and the trace amounts of debris left on the printing plate after imaging were easily removed by the fountain solution on-press. The fully imaged areas that were not cleaned printed white background as observed from the beginning of the print test. In this case it was possible to achieve literally processless plates by ablation.

In addition, the lithographic printing plate of Invention Example 5 exhibited a much improved print run length compared to that described for Comparative Example 2. This suggests that adding the VP11 copolymer to the crosslinked hydrophilic inner layer improved the image adhesion and print run length even without subjecting the surface of the sulfuric anodized aluminum substrate to a treatment of the VP11 copolymer. Furthermore, the lithographic printing plate of Invention Example 5 exhibited an improved print run length compared to that described for Invention Example 4. This shows that using an increased amount of the VP 11 copolymer in the crosslinked hydrophilic inner layer provided improved print run length.

At the level of the VP11 copolymer used in the lithographic printing plate precursor of Invention Example 5, it was possible to obtain an improved print run length compared to that obtained with the lithographic printing plate of Comparative Example 1.

### Invention Example 6

Lithographic printing plate precursors of the present invention were prepared using the same general procedure described above for Invention Example 4, but an electrochemically roughened and phosphoric acid anodized aluminum substrate was used. As in Invention Example 4 and Comparative Example 1, the substrate was not subjected to a treatment with the VP11 copolymer.

A sample of the precursor was exposed at 1500 mJ/cm² using a Kodak® Lotem 400 Quantum imager (having 1 bar of diodes, 224 valves and overall intensity of 25 Watt). The imaged precursor was gently wet cleaned with water, removing the black material still left on the imaged background. The imaged precursors of Invention Example 6 and Comparative Example 1 were then mounted together on a Ryobi 520HX printing press so that their print run lengths could be compared in the same printing test. The number of impressions needed to reach a wear of more than 20% reduction in printed dots size of fine features (2 and 5% dots at 200 lpi screen) was used to compare the print performance of the imaged precursor used. Both lithographic printing plates showed good image quality and the lithographic printing plate of Invention Example 6 showed a print run length of 129% (for 2% dots at 200 lpi screen) and 156% (for 5% dots at 200 lpi screen) of that obtained with the standard lithographic printing plate of Comparative Example 1.

A white printed background was obtained, corresponding to a fully imaged area on the imaged precursor, as observed from the beginning of the print test. When the imaged precursor was mounted on-press without first water cleaning it, the white printed background was obtained only after about 50 impressions, that is the black material left on the imaged background was removed on-press and in this case the imaged precursor was developed on-press. However, when a sample of the Invention Example 6 precursor was imaged using a more powerful laser of a Kodak® Thermo Flex 400 imager (having 48 diodes of 1 Watt each), the imaged areas on the imaged precursor were almost completely clean after imaging (only trace amounts of debris left in the imaged background). In this case, the imaged precursor was not cleaned after imaging and the trace amounts of debris left on the imaged precursor were easily removed by the fountain solution on-press. The fully imaged areas that were not cleaned printed white background, as observed from the beginning of the print test. Therefore, it was possible to achieve literally processless plates by ablation.

The lithographic printing plate of Invention Example 6 exhibited a somewhat improved print run length compared to that described in Invention Example 4. As mentioned in Invention Example 1, this could be due to the very different topography of the two different anodized aluminum substrates that were observed in scanning electron micrographs of the two substrates. Without being bound to a particular mechanism or explanation, it could be that in this situation, the hydrophilic inner layer formulation was able to better penetrate into the phosphoric acid anodized aluminum anodic surface, thus improving the adhesion of the resulting hydrophilic inner layer to the substrate and also improving the resulting image adhesion, leading to a much improved print run length.

In addition, the lithographic printing plate of Invention Example 6 exhibited an improved print run length compared to that described for Comparative Example 1. This demonstrates that adding the VP11 copolymer to the crosslinked inner hydrophilic layer can improve the image adhesion and print run length when a phosphoric acid anodized aluminum substrate is used, even without subjecting the surface of the phosphoric acid anodized aluminum substrate to a treatment of the VP11 copolymer.

### Solvent Resistance of the Various Lithographic Printing Plate Precursors:

Polymer MN-24 can be dissolved in PM or in a PM:MEK mixture that is used in the oleophilic surface layer formulation. However, coatings containing this polymer are not soluble with PM.

The resistance to press chemicals of the positive-working ablation-imagable lithographic printing plate precursors prepared in Invention Examples 1-6 were evaluated using the following tests:

Solvent Resistance Tests:

Four solvent mixtures were used for these tests:

(1) Butyl Cellosolve (“BC”, 2-butoxyethanol) test, 80% in water

(2) UV Wash test (“Glycol Ether” blends)

(3) Diacetone Alcohol test (“DAA”, 80% in water)

(4) Heatset Fountain Solution E9069/3 test at two different concentrations, 100% and 8% in water. Heatset Fountain Solution E9069/3 is commercial product that comprises 2-(2-butoxyethoxy)ethanol, Bronopol, ethanediol, and propan-2,1-diol.

For each test, drops of each solvent solution were placed on a 35% screen (175 lpi) region of each imaged lithographic printing plate precursor that has been wet cleaned with water, and then the drops of each solvent solution were removed with a cloth. Each test was carried out at about 23° C. A measurement of less than 5% reduction in the dot size (in regions on the 35% screen where drops of the solvent solutions were present, compared to areas that had no solvent contact) is considered acceptable. The dot size before and 20 minutes after the solvent solution contact was measured using a spectroplate. After the solvent solution drops were left on each imaged precursor for 20 minutes, each imaged precursor was then mounted onto a Ryobi 520HX printing press and 5000 impressions were made to see if the dots remained on the lithographic printing plates. A spectrodense was used to measure the dot area on the printed impressions that corresponded to the regions on the printing plate precursors that had contact with the solvent solutions and also those regions that had no contact with the solvent solutions. As noted above, a measurement of less than 5% reduction in the dot size (in regions on the printed impressions corresponding to the 35% screen) is considered acceptable.

Excellent solvent resistance was found for the lithographic printing plate precursors prepared in Invention Examples 1-6 for all solvent solutions used in the evaluations.

The invention has been described in detail with particular reference to certain preferred embodiments thereof, but it will be understood that variations and modifications can be effected within the spirit and scope of the invention.

1. A positive-working, ablation-imagable lithographic printing plate precursor comprising, in order:
a sulfuric acid or phosphoric acid anodized aluminum-containing substrate,
a crosslinked hydrophilic inner layer comprising; (1) a crosslinked polymer derived by crosslinking a hydrophilic polymer comprising randomly recurring units represented by —CH₂—CH(OH)— in an amount of at least 70 mol % of the total recurring units, using a crosslinking agent for the —CH₂—CH(OH)— recurring units that comprises at least two aldehyde groups, and (2) an acidic compound,
over the crosslinked hydrophilic inner layer, an oleophilic outer layer comprising: (a) an infrared radiation absorber, and (b) at least one oleophilic polymer that comprises at least 10 mol % randomly recurring units represented by —CH₂—CH(OH)—, based on the total recurring units, and
the crosslinked hydrophilic inner layer and the oleophilic outer layer forming a composite structure of the two layers,
the positive-working, ablation-imagable lithographic printing plate precursor further comprising a copolymer comprising randomly recurring units derived from each of a (meth)acrylamide and vinyl phosphonic acid,
wherein the copolymer is present either:
(a) within the crosslinked hydrophilic inner layer,
(b) within a different copolymer layer between the crosslinked hydrophilic inner layer and the sulfuric acid or phosphoric acid anodized aluminum-containing substrate, or
(c) both (a) and (b).

2. The positive-working ablation-imagable lithographic printing plate precursor of claim 1, wherein the aluminum-containing substrate is a sulfuric acid anodized aluminum-containing substrate.

3. The positive-working ablation-imagable lithographic printing plate precursor of claim 1, wherein the copolymer is present within the crosslinked hydrophilic inner layer.

4. The positive-working ablation-imagable lithographic printing plate precursor of claim 1, wherein the copolymer comprises at least 70 mol % of randomly recurring units derived from a (meth)acrylamide and at least 5 mol % of recurring units derived from vinyl phosphonic acid, based on total recurring units in the copolymer.

5. The positive-working ablation-imagable lithographic printing plate precursor of claim 1, wherein the copolymer comprises at least 80 mol % and up to and including 90 mol % of randomly recurring units derived from a (meth)acrylamide and at least 10 mol % and up to and including 20 mol % of recurring units derived from vinyl phosphonic acid, based on total recurring units in the copolymer.

6. The positive-working ablation-imagable lithographic printing plate precursor of claim 1, wherein the copolymer consists only of randomly recurring units derived from each of a (meth)acrylamide and vinyl phosphonic acid.

7. The positive-working ablation-imagable lithographic printing plate precursor of claim 1, wherein the copolymer further comprises up to and including 25 mol % randomly recurring units derived from one or more ethylenically unsaturated polymerizable monomers other than (meth)acrylamides and vinyl phosphonic acid.

8. The positive-working ablation-imagable lithographic printing plate precursor of claim 1, wherein the oleophilic polymer comprises randomly recurring acetal units that are represented by Structure (Ia): 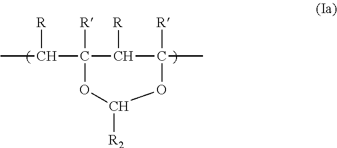
wherein R and R′ are independently hydrogen or a substituted or unsubstituted alkyl group, a substituted or unsubstituted cycloalkyl group, or a halo group,
a) R₂ is a phenyl or naphthyl group that has a cyclic aliphatic or aromatic imide group selected from the group consisting of maleimide, phthalimide, tetrachlorophthalimide, hydroxyphthalimide, carboxypthalimide, nitrophthalimide, chlorophthalimide, bromophthalimide, and naphthalimide groups, wherein the phenyl, naphthyl, or cyclic aliphatic or aromatic imide group is optionally further substituted with one or more substituents selected from the group consisting of hydroxyl, alkyl, alkoxy, and halo groups, or
b) R₂ is a nitro-substituted phenol, nitro-substituted naphthol, or nitro-substituted anthracenol, and
when the oleophilic poly(vinyl acetal) comprises a combination of two or more different randomly recurring acetal units represented by Structure (Ia), R₂ represents two or more different groups listed in a) and b).

9. The positive-working ablation-imagable lithographic printing plate precursor of claim 1, wherein the oleophilic polymer is a poly(vinyl acetal) that comprises randomly recurring units represented by Structure (Ib): 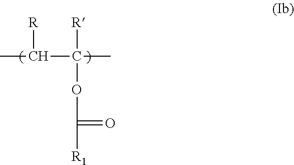
wherein R and R′ are independently hydrogen or a substituted or unsubstituted alkyl group, a substituted or unsubstituted cycloalkyl group, or a halo group, and R₁ is a substituted or unsubstituted linear or branched alkyl group having 1 to 12 carbon atoms, a substituted or unsubstituted cycloalkyl having 5 to 10 carbon atoms in the carbocyclic ring, or a substituted or unsubstituted aryl group having 6 or 10 carbon atoms in the aromatic ring.

10. The positive-working ablation-imagable lithographic printing plate precursor of claim 1, wherein the oleophilic polymer comprises randomly recurring units represented by one or both of the following Structures (Ic) and (Id): 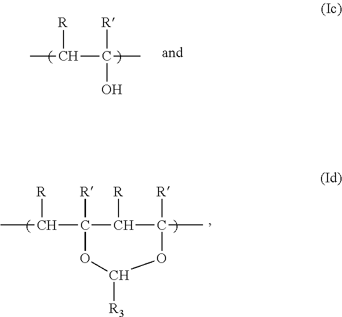
wherein R and R′ are independently hydrogen or a substituted or unsubstituted alkyl group, a substituted or unsubstituted cycloalkyl group, or a halo group,
R₃ is hydrogen or a substituted or unsubstituted alkyl group, a substituted or unsubstituted cycloalkyl group, or an aryl group that is unsubstituted or substituted with at least one hydroxy group.

11. The positive-working ablation-imagable lithographic printing plate precursor of claim 1, wherein the crosslinked hydrophilic polymer is present in the inner layer formulation in an amount of at least 50% solids.

12. The positive-working ablation-imagable lithographic printing plate precursor of claim 1, wherein the hydrophilic polymer has been crosslinked with ethane-1,2-dial.

13. The positive-working ablation-imagable lithographic printing plate precursor of claim 1, wherein the acidic compound is phosphoric acid that is present in the crosslinked hydrophilic inner layer in an amount of at least 1 weight % based on the total crosslinked hydrophilic inner layer dry weight.

14. The positive-working ablation-imagable lithographic printing plate precursor of claim 1, wherein the oleophilic polymer is present in the oleophilic outer layer formulation in an amount of at least 50 weight % and up to and including 95 weight % based on total oleophilic outer layer dry weight.

15. The positive-working ablation-imagable lithographic printing plate precursor of claim 1, wherein the oleophilic outer layer comprises an infrared radiation absorber that is a carbon black.

16. The positive-working ablation-imagable lithographic printing plate precursor of claim 1, wherein the surface of the composite structure exhibits less than 10% optical density change within a first rectangular area defined by width W1 and length L1 centered inside a second rectangular area defined by width W2 and length L2, where the surface of the composite structure is subjected to 1000 rubs according to ASTM D3181 using an organic solvent solution used to form the oleophilic outer layer, wherein W1 is 0.7 times W2, L1 is 0.7 times L2, W2 is 1.5 cm, and L2 is 12 cm.

17. A method for providing a lithographic printing plate, comprising:
imagewise exposing the positive-working ablation-imagable lithographic printing plate precursor of claim 1 to remove the oleophilic outer layer in exposed regions by ablation to prepare a lithographic printing plate ready for printing without further treatment or processing.

18. The method of claim 17, comprising imagewise exposing using infrared radiation at an energy of at least 1 J/cm².

19. The method of claim 17, further comprising:
wherein without intermediate contact with a solution after the imagewise exposing, using the lithographic printing plate for lithographic printing.

20. A method for preparing a positive-working, ablation-imagable lithographic printing plate precursor, the method comprising:
providing a sulfuric acid or phosphoric acid anodized aluminum-containing substrate,
over the sulfuric acid or phosphoric acid anodized aluminum-containing substrate, providing a crosslinked hydrophilic inner layer by applying an inner layer formulation comprising: (1) a hydrophilic polymer that comprises randomly recurring units represented by —CH₂—CH(OH)— in an amount of at least 70 mol % of the total recurring units, (2) a crosslinking agent for the —CH₂—CH(OH)— recurring units that comprises at least two aldehyde groups, and (3) an acidic compound,
over the crosslinked hydrophilic inner layer, providing an oleophilic outer layer by applying an outer layer formulation comprising: (a) an infrared radiation absorber, and (b) at least one oleophilic polymer that comprises at least 10 mol % randomly recurring units represented by —CH₂—CH(OH)—, based on the total recurring units, dissolved or dispersed within an organic solvent solution, and drying to form a composite structure consisting of the crosslinked hydrophilic inner layer and the oleophilic outer layer, and
the method further comprising:
providing a copolymer comprising randomly recurring units derived from both a (meth)acrylamide and vinyl phosphonic acid,
wherein the copolymer is provided either:
(a) as part of the inner layer formulation,
(b) by applying a different layer of the copolymer directly to the sulfuric acid or phosphoric acid anodized aluminum-containing substrate before applying the inner layer formulation, or
(c) both (a) and (b).
